(19) United States
(12) Patent Application Publication
(10) Pub. No.: US 2026/0282433 A1
(43) Pub. Date: Sep. 17, 2026

(54) RADIATION HARDENED FIELD EFFECT TRANSISTOR WITH DOPED BUFFER LAYER

(71) Applicant: Microchip Technology Incorporated, Chandler, AZ (US)

(72) Inventors: Shesh Mani Pandey, Gilbert, AZ (US); Yogesh Kumar Sharma, Colorado Springs, CO (US)

(73) Assignee: Microchip Technology Incorporated, Chandler, AZ (US)

(21) Appl. No.: 19/559,403

(22) Filed: Mar. 6, 2026

Related U.S. Application Data
(60) Provisional application No. 63/771,229, filed on Mar. 13, 2025.

(51) Int. Cl. H10D 30/66; H10D 30/01; H10D 62/60; H10P 30/20

(52) U.S. Cl. CPC H10D 30/662; H10D 30/0291; H10D 62/60; H10P 30/212

(57) ABSTRACT

A field effect transistor (FET) that is radiation-hardened against a single-event burnout effect comprises a volume of semiconductor material, a gate, a source, a drain, a drift region, and a doped drift region. The gate is positioned at a first end of the structure. The source is positioned at the first end of the structure. The drain is spaced apart from the source. The drift region is positioned between the source and the drain. The doped region includes a plurality of doped zones spaced apart from one another and positioned between the drain and the drift region. The doped drift region is configured to provide radiation hardening against a single event burnout.

### CROSS-REFERENCE TO RELATED APPLICATIONS

The current patent application is a non-provisional utility patent application which claims priority benefit of earlier-filed U.S. Provisional Application Ser. No. 63/771,229; titled “RADIATION HARDENED FIELD EFFECT TRANSISTOR WITH DOPED BUFFER LAYER”; and filed Mar. 13, 2025. The Provisional Application is hereby incorporated by reference, in its entirety, into the current patent application.

### FIELD

Various examples of the current technology relate to improved field effect transistors that provide radiation hardening against a single event burnout.

### BACKGROUND

A metal oxide semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

The background discussion is intended to provide information related to the present technology which is not necessarily prior art.

### SUMMARY

Various examples of the current technology address one or more of the above-mentioned problems and provide field effect transistors and methods of fabricating field effect transistors that are radiation hardened against a single event burnout by including a doped drift region having a plurality of doped zones that are spaced apart from one another. An example of the field effect transistor comprises a volume of semiconductor material, a gate, a source, a drain, a drift region, and a doped drift region. The volume of semiconductor material includes vertically spaced first and second ends. The gate is positioned adjacent the first end of the structure. The source is positioned adjacent the first end of the structure. The drain is spaced apart from the source. The drift region is formed by the volume of semiconductor material between the source and the drain. The doped region includes a plurality of doped zones spaced apart from one another and positioned between the drain and the drift region. The doped drift region is configured to provide radiation hardening against a single event burnout.

The preceding example may include any one or more of the following features. The FET may comprise a buffer layer positioned between the drain and the doped drift region. The buffer layer may be formed from a doped material having a higher dopant concentration than the drain and the doped drift region. The doped zones may have a dopant concentration that is higher than the remaining portion of the doped drift region but is lower than the buffer layer. The doped zones and the drain may have similar dopant concentrations. The drift region may comprise N- material, the doped drift region comprising N- material, the doped zones may comprise N+ material, the drain may comprise N+ material, and the buffer layer may comprise N++ material. The drain may be positioned at the second end of the volume of semiconductor material. The FET may include a gate oxide positioned between the gate and the source and formed from electrically insulating material or dielectric material. The gate oxide may include a thick section positioned over a JFET neck region of the drift region. The doped zones may be distributed in a plurality of rows. Each of the rows may be positioned at a respective one of a plurality of depths in the doped drift region. Each of the rows may include a respective set of the doped zones spaced laterally apart from one another, such that adjacent ones of the doped zones in the respective set define a space therebetween. Each of the doped zones in one row may be vertically aligned with the space between adjacent doped zones in one or more adjacent row(s). Each of the doped zones in one row may be laterally spaced apart from neighboring doped zones in one or more adjacent row(s). Each of the doped zones may have a generally rectangular cuboid shape.

An example of the method comprises forming a volume of semiconductor material to include first and second vertically spaced ends; forming a gate adjacent adjacent the first end of the volume of semiconductor material; forming a source adjacent adjacent the first end of the volume of semiconductor material; providing a drain spaced apart from the source, such that the volume of semiconductor material defines a drift region between the source and the drain; and forming a doped drift region between the drain and the drift region. The operation of forming the doped drift region includes forming a plurality of doped zones spaced apart from one another and configured to provide radiation hardening against a single event burnout.

The preceding examples may include any one or more of the following features. The method may comprise forming a buffer layer between the drain and the doped drift region. The operation of forming the buffer layer being performed so that the buffer layer has a higher dopant concentration than the drain and the doped drift region. The operation of forming the doped zone may be performed so that the doped zones have a higher dopant concentration than the remaining portion of the doped drift region but lower than the buffer layer. The operation of providing the drain may be performed so that the drain and the doped zones have similar dopant concentrations. The operations of forming the doped drift region and the doped zones may include locating the doped zones into a plurality of rows positioned at a respective depths of the doped drift region, with each of the rows including a respective set of the doped zones spaced laterally apart from one another, such that adjacent ones of the doped zones in the respective set define a space therebetween. The operation of locating the doped zones into each of the rows may include forming a doped material through a respective one of a plurality of masks, each mask including openings in a plurality of locations, each location corresponding to a lateral position of the doped zones for a given row of doped zones. The operation of forming the doped material through the respective masks may include implanting the doped material at a respective one of a plurality of energy levels which vary according to the depth of the row of doped zones. The step of locating the doped zones may include vertically aligning the doped zones in one row with the space between adjacent doped zones in one or more adjacent row(s). The operation of locating the doped zones may include laterally spacing the doped zones in one row from neighboring doped zones in one or more adjacent row(s).

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current technology will be apparent from the following detailed description of the various examples and the accompanying drawing figures.

### BRIEF DESCRIPTION OF DRAWINGS

Various examples of the current technology are described in detail below with reference to the attached drawing figures, wherein:

FIG. 1 is a schematic cross-sectional view of a radiation hardened field effect transistor, constructed in accordance with various examples of the current technology and including an additional buffer layer having a plurality of doped or implanted zones;

FIGS. 2A, 2B, 2C, 2D, 2E, 2F, and 2G illustrate portions of the field effect transistor during a plurality of operations of a method for fabricating the radiation hardened field effect transistor; and

FIG. 3 includes a listing of at least a portion of the operations of the method for fabricating the radiation hardened field effect transistor.

The drawing figures do not limit the current technology to the specific examples disclosed and described herein. The drawings are not necessarily to scale, emphasis instead being placed upon clearly illustrating the principles of the technology.

### DETAILED DESCRIPTION

The following detailed description of the technology references the accompanying drawings that illustrate specific examples in which the technology can be practiced. The various examples are intended to describe aspects of the technology in sufficient detail to enable those skilled in the art to practice the technology. Other examples can be utilized and changes can be made without departing from the scope of the current technology. The following detailed description is, therefore, not to be taken in a limiting sense. The scope of the current technology is defined only by the appended claims, along with the full scope of equivalents to which such claims are entitled. In addition, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In the following description, the word “voltage” may be used to describe electric voltage, the word “current” may be used to describe electric current, and the word “power” may be used to describe electric power. Relational and/or directional terms, such as “above,” “below,” “up,” “upper,” “upward,” “down,” “lower,” “downward,” “top,” “bottom,” “outer,” “inner,” “left,” “right,” etc., along with orientation terms, such as “horizontal” and “vertical,” may be used throughout this description. These terms retain their commonly accepted definitions and are used with reference to embodiments of the technology and the positions, directions, and orientations thereof shown in the accompanying figures. However, examples of the technology in practice may be positioned and oriented in other ways or move in other directions. Therefore, the terms do not limit the scope of the current technology.

Field-effect transistors (FETs), such as metal oxide semiconductor FETs (MOSFETs) and junction FETs (JFETs), are semiconductor material devices that include three terminals, a gate, a drain, and a source, wherein a voltage is applied to one of the terminals, i.e., the gate, in order to control current flow between the other two terminals, i.e., the drain and the source. Silicon (Si) is typically used as the semiconductor material, although in high voltage applications, silicon carbide (SiC) is utilized – resulting in a SiC power FET. When SiC power FETs are used in certain applications, they may be exposed to radiation. For example, when a SiC power MOFET is used in space, it may be exposed to radiation that it would not experience in terrestrial applications. This radiation can cause failure or destruction of the SiC power MOSFET. For example, a single-event burnout (SEB) is a catastrophic single-event effect failure mechanism initiated by the passage of heavy ions through the active region of power FETs. In SEB, electron-hole pair production from a heavy ion strike causes a vertical parasitic negative-positive-negative bipolar junction transistor (NPN BJT), which includes base, collector, and emitter terminals and is inherently formed in the FET device structure, to switch on when the device is in the off-blocking state (i.e., the drain-source voltage (VDS) is positive). If the regenerative feedback mechanism is unsuppressed, the collector (i.e., the drain side of the NPN) currents in the parasitic vertical NPN BJT can increase enough to burn out the BJT and create a permanent short between the source and the drain. More specifically, in SEB, the parasitic BJT is sufficiently triggered to enter into the secondary breakdown or "snap back" mode. In an unenhanced (i.e., non-radiation hardened) commercial SiC device, the heavy ion strike temporarily (on the order of picoseconds) expands the depletion region edge from N- epitaxial to N++ substrate and begins secondary breakdown at the N++ substrate/N- epitaxial interface. Due to extra current flow in the P-base/body from secondary breakdown and the non-zero resistance of the P-base/body region, this creates a positive body-emitter voltage (VBE) bias in the parasitic NPN, which turns it on. If the parasitic NPN gain is too high, then the electron current in the collector exceeds the epitaxial (drain/collector) doping level, causing the collector to enter the high-injection regime. This pushes the depletion region on the collector (drain) side further into the N++ substrate, which leads to a complete avalanche breakdown and massive surge of current which potentially destroys the device.

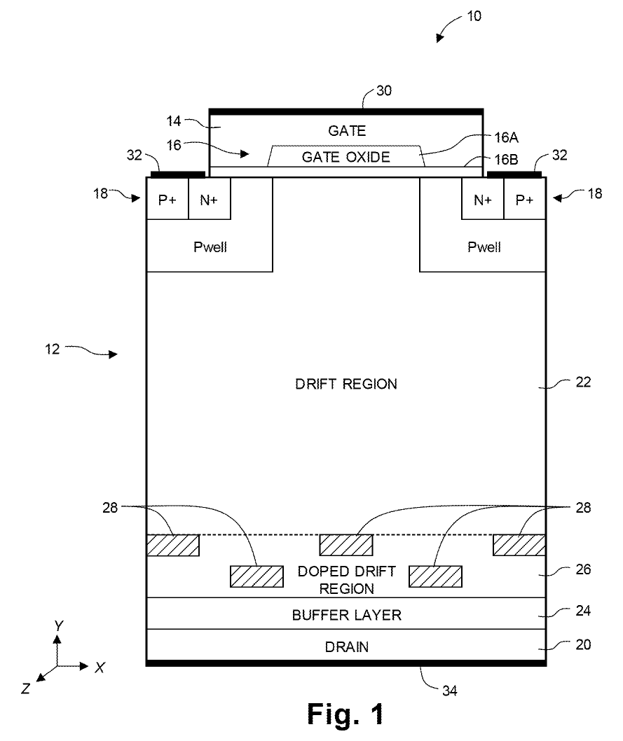

Referring to FIG. 1, an improved SiC power FET 10 that is radiation hardened against an SEB event is shown. Examples of the FET 10 shown in the figures include a MOSFET, although the principles of the current technology apply to other active devices as well, including a JFET. One with ordinary skill in the art will recognize that the technology described herein may, when applicable, be implemented in enhancement mode or depletion mode. Further, the technology described herein may, when applicable, be implemented as an N-channel or a P-channel device, wherein, in general, regions that are N-doped or P-doped in N-channel implementations may be, respectively, P-doped or N-doped in P-channel implementations. The FET 10 is a structure broadly comprising a volume of semiconductor material 12, a gate 14, a gate oxide 16, a source 18, a drain 20, a drift region 22, a buffer layer 24, and a doped drift region 26.

It will also be appreciated that the sides of the illustrated volume of semiconductor material 12 are defined herein merely to represent a portion of semiconductor material relative to the illustrated FET 10. In practice, the volume of semiconductor material 12 may extend laterally beyond the bounds illustrated in the drawings (leftward and rightward along an X direction when viewing FIG. 1) to present additional semiconductor material in which additional devices may be provided. Such additional devices may be MOSFETs (which may be similarly or alternatively constructed to the FET 10) or may be entirely different devices providing different operations or functions than the FET 10.

The volume of semiconductor material 12 presents a first (or top) end, a second (or bottom) end opposite and vertically spaced (along a Y direction) from the first end, a first (or left) side, and a second (or right) side opposite and laterally spaced (along the X direction) from the first side. In addition, the volume of semiconductor material 12 may have a front end and a back end opposite and axially spaced (along a Z direction) from the front end. The volume of semiconductor material 12 may be constructed from or include an N- epitaxial semiconductor material. In the illustrated example, the first end of the volume of semiconductor material is planar with the FET components (described further below) being located at and along the first end. However, according to some aspects of the example FET, a trench (not shown) may extend from the first end and one or more of the FET components may be located within the trench. The volume of semiconductor material 12 may may comprise SiC.

The gate 14 is formed from polysilicon, a metal or alloy of metals, or other suitable material and is positioned above the first end of the volume of semiconductor material 12. The gate 14 includes a top wall, a left side wall, and a right side wall. The top wall has an upper surface and a lower surface. The left side wall extends downward from a left edge of the top wall, and the right side wall extends downward from a right edge of the top wall. The downward extension of the left and right side walls creates the boundaries for a space underneath the top wall adjacent to the lower surface.

In MOSFET applications, positioned between the gate 14 and the source 18 is the gate oxide 16, which is formed from silicon dioxide, aluminum dioxide (Al2O3), hafnium dioxide, silicon nitride, or other suitable electrically insulating or dielectric material. The gate oxide 16 may include a thick oxide section 16A positioned in the space beneath the lower surface of the top wall of the gate 14. A thin oxide section 16B may extend along the width of the gate 14, with opposite end portions of the thin oxide section 16B being positioned between the source 18 and opposite end portions of the gate 14, and a central portion of the thin oxide 16B portion being located between the thick oxide section 16A and the underlying structure. It is further noted that the thick oxide section 16B may be generally over a portion of the drift region 22 referred to as a JFET neck region. The JFET neck region extends to the first end of the volume of semiconductor material and is located between the side structures of the FET (as described further below).

The source 18 is positioned adjacent the first end of the volume of semiconductor material 12. Further, the source 18 may generally be split into two (2) source sections positioned adjacent the left and right sides of an upper region of the volume of semiconductor material 12. A left side section is positioned on the left side of the volume of semiconductor material 12 and may include an N+ material, and a right side section is positioned on the right side of the volume of semiconductor material 12 and may include an N+ material. Left and right wells are provided adjacent the respective left and right side sections of the source 18. A body contact (or doped region) is located at the first end on the opposite side of the respective source section from the well. The body contact may be formed of P+ material and the well may be formed of P material. Each well extends from the first end of the volume of semiconductor material 12 at a location inwardly (closer to the center of the FET 10) from the respective source section and also underlies the respective source section and body contact. In the illustrated example, the FET 10 side structures (each comprising the corresponding source section, well, and body contact) are mirror images of one another, although side structures having different configurations are within the ambit of certain aspects of the example FET 10. The illustrated gate 14, gate oxide 16, and FET side structures are located at and along (above or below) the first end, which is planar, thereby defining a planar MOSFET. However, according to certain examples, the gate, gate oxide, source, well, and/or body contact may be otherwise located, e.g., spaced within a trench of the volume of semiconductor material. In such instances, the FET may be considered a trench FET.

Because of the laterally spaced side structures, the illustrated MOSFET 10 is a so-called dual channel MOSFET, in which a channel is formed along each of the wells. However, it shall be understood that certain aspects contemplate a single channel MOSFET, in which a single source, well, and body contact are provided (rather than laterally spaced side structures).

The drain 20 is a layer of doped material spaced from the source. In the illustrated example, the drain 20 is located at the second end of the volume of semiconductor material 12, although certain examples contemplate alternative positioning of the drain, such as at or adjacent the first end of the volume of semiconductor material. The drain 20 may be formed from or include an N+ material.

The drift region 22 includes the JFET neck region (described above) and extends from the first end of the volume of semiconductor material 12 between the two (2) sections of the source 18 toward the drain 20. Therefore, in the illustrated example, the drift region 22 extends toward the second end of the volume of semiconductor material 12. The drift region 22 provides a pathway for one or more channel(s) through which the majority charge carriers move and the electric current flows between the source and the drain. The drift region 22 may be formed from N- doped epitaxial (epi) material.

The buffer layer 24 is positioned between the drift region 22 and the drain 20. In the illustrated example, the buffer layer 24 is positioned above the drain and, more preferably, immediately adjacent the drain. The buffer layer may be formed from N++ (highly) doped material.

The doped drift region 26 is positioned adjacent (in the illustrated example, above) the buffer layer 24. The doped drift region 26 may be formed from N- doped epi material and includes a plurality of doped zones 28, wherein each doped zone 28 may be formed from highly-doped N+ material, although other materials may be used. (The doped drift region 26 may be considered an extension of the drift region 22 in which there are doped zones 28. Further, the channel(s) extend through the doped drift region 26.)

In the illustrated example, the buffer layer 24 has a higher dopant concentration than the drain 20 and the doped drift region 26. The buffer layer 24 may also have a higher dopant concentration than the doped zones 28. Other than the doped zones 28, the doped drift region 26 may have a similar dopant concentration as the drift region 22. The doped zones 28 and the drain 20 may have similar dopant concentrations.

Each doped zone 28 may have a generally rectangular cuboid shape with a height, or depth (along the Y direction), a width (along the X direction), and an axial length (along the Z direction). The doped zones 28 may be distributed in the doped drift region 26 in a plurality of rows, wherein a respective set the doped zones 28 are positioned in each row. In addition, each row may be positioned at a respective one of a plurality of depths (along the Y direction) in the doped drift region 26. The doped zones 28 may be laterally spaced apart from one another in each row. Furthermore, the doped zones 28 may be offset from one another in adjacent rows such that each doped zone 28 in one row may be vertically aligned with a space between adjacent doped zones 28 in one or more adjacent row(s). In addition, there may be lateral space between each doped zone 28 in one row and the neighboring doped zones 28 in one or more adjacent row(s). In other words, the doped zones 28 may be configured to avoid any overlap (and in fact be laterally spaced from) the doped zones 28 of adjacent row(s). The illustrated doped drift region 26 includes three (3) doped zones 28 in a first row and two (2) doped zones 28 in a second row. However, the doped drift region 26 may include a greater number of doped zones 28 per row and/or a greater number of rows.

The FET 10 additionally comprises a plurality of contacts, or electrodes, which provide electrical contact between various components and bond wires that connect to a package for the FET 10. Specifically, the FET 10 includes a gate contact 30 to provide electrical contact with the gate 14, a source contact 32 to provide electrical contact with the source 18, and a drain contact 34 to provide electrical contact with the drain 20. Each contact is formed from metals or metal alloys.

The doped drift region 26 provides radiation hardening, that is, reduced susceptibility to the SEB, by lowering the electric field between the drift region 22 and the drain 20 by reducing the ionization impact at the drift region 22/buffer layer 24 junction. Such an arrangement is particularly beneficial in SiC MOSFETs.

Relatedly, a structure or region may contain two or more different doping doses. For example, one with ordinary skill in the art will recognize that some P-wells may contain a lower dose P-well portion and a higher dose unclamped inductive switching portion.

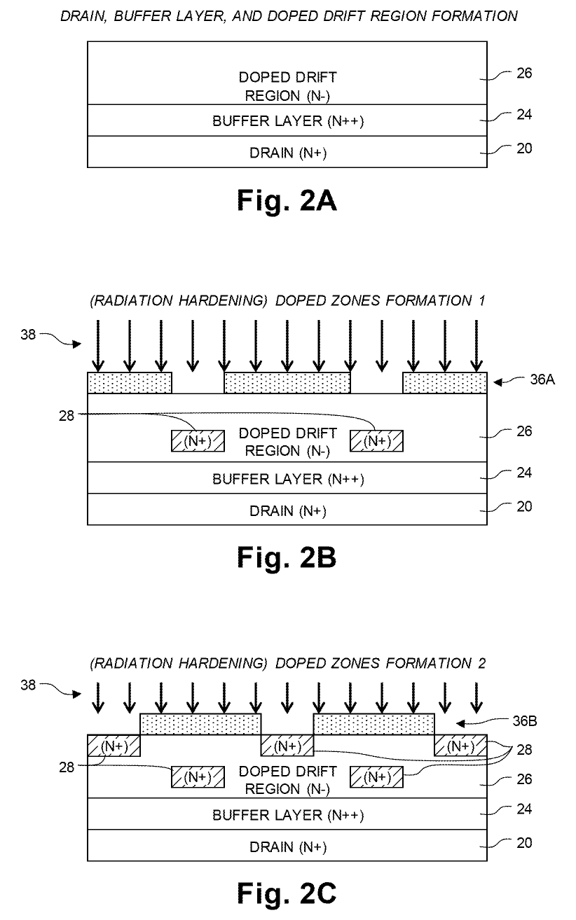

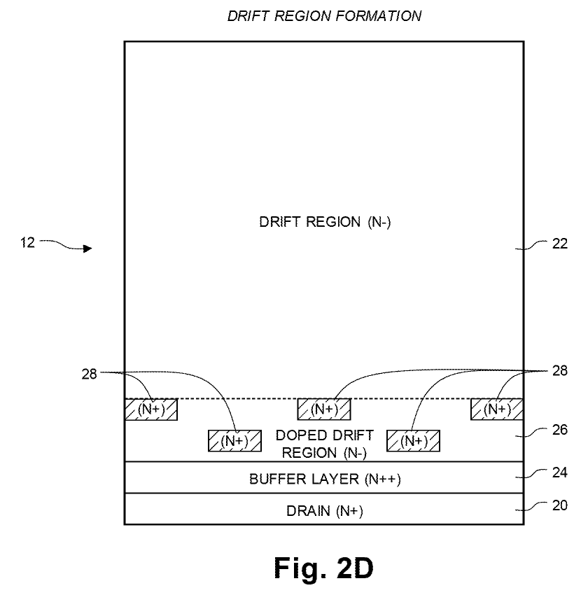

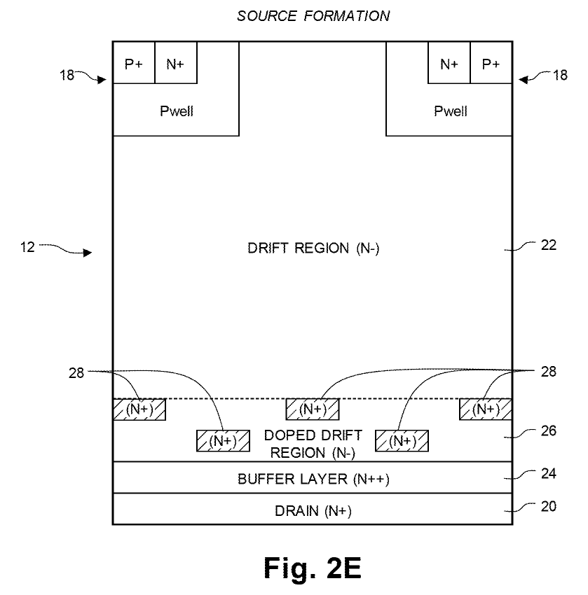

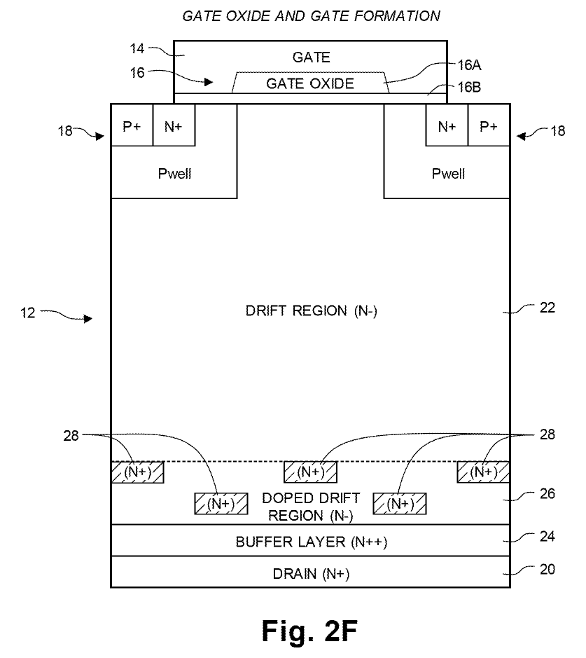

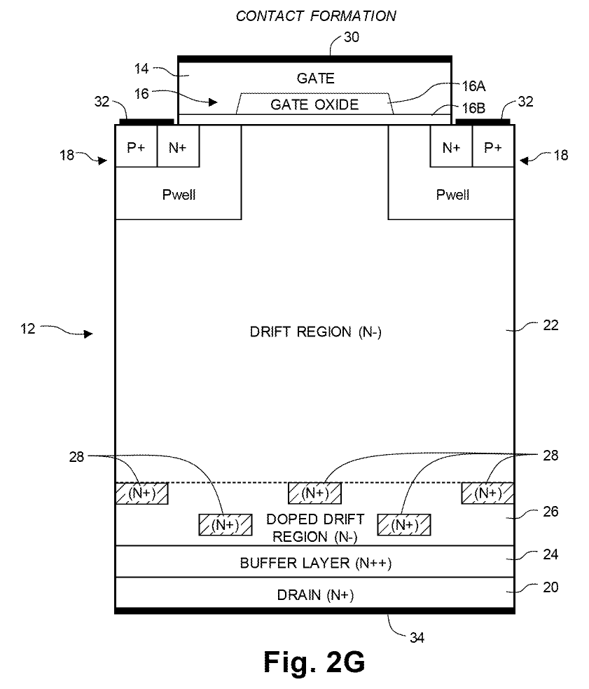

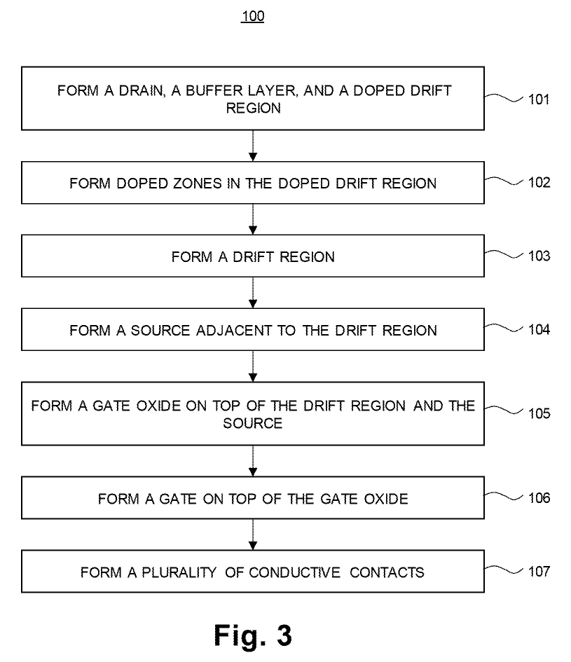

Referring to FIGS. 2A-2F, portions of the FET 10 are shown during various operations of a method 100 fabricating the FET 10. In addition, each operation of the method 100 may be listed in a respective one of a plurality of blocks shown in FIG. 3. Each operation discussed may include numerous sub operations.

Referring to block 101 and FIG. 2A, a drain 20, a buffer layer 24, and a doped drift region 26 are formed. The drain 20, the buffer layer 24, and the doped drift region 26 may be formed in a stack. The drain 20 may be an N+ substrate and semiconductor material, including the volume of semiconductor material 12, may may be formed utilizing various deposition techniques for epitaxial crystal growth. The semiconductor material may be grown to a height of a top of the doped drift region 26. The buffer layer 24 may be provided by implanting N++ material into the semiconductor material on top of the drain 20. The doped drift region 26 (minus the doped zones 28) is then formed by implanting the semiconductor material with N- material (or the N- material may be provided as part of the epitaxial growth of the semiconductor material.

Referring to block 102 and FIGS. 2B and 2C, a plurality of doped zones 28 are formed in the doped drift region 26. Each doped zone 28 is formed from highly-doped N+ material, although other materials may be used. The doped zones 28 are distributed in the doped drift region 26 in a plurality of rows, wherein a respective sets of the doped zones 28 are positioned in each row. In addition, each row is positioned at a particular depth in the doped drift region 26 and the respective portion of the doped zones 28 are spaced apart from one another in each row. Furthermore, the doped zones 28 are offset from one another in adjacent rows such that each doped zone 28 in one row is vertically aligned with a space between adjacent doped zones 28 in one or more adjacent row(s). In addition, there is lateral space between each doped zone 28 in one row and the neighboring doped zones 28 in one or more adjacent row(s).

The doped zones 28 are formed by placing a respective one of a plurality of masks over the doped drift region 26, wherein the mask includes openings in a plurality of locations, with each location being the lateral position of a respective one of the doped zones 28 in a given row. N+ material 38 is implanted through the mask with an energy level that varies according to a depth (along the Y direction) of the given row, wherein, generally, a greater energy level results in a greater depth of the row of doped zones 28, and a smaller energy level results in a smaller depth. For example with reference to FIG. 2B, a first mask 36A is utilized which has openings for a first portion of the doped zones 28 in a first row (at a first depth). N+ material 38 is implanted with a first energy level to provide the first depth of the first row of doped zones 28. Referring to FIG. 2C, a second mask 36B is utilized which has openings for a second portion of the doped zones 28 in a second row (at a second depth). N+ material 38 is implanted with a second energy level to provide the second depth of the second row of doped zones 28, wherein the second energy level is less than the first energy level, given that the second row of doped zones 28 is shallower than the first row of doped zones 28. Each resulting doped zone 28 may have a generally rectangular cuboid shape with a height, or depth (along the Y direction), a width (along the X direction), and an axial length (along the Z direction).

An alternative approach to forming the doped zones 28 involves etching and deposition. For example, a first portion of the doped drift region 26 may be grown, or formed, on the buffer layer 24 up to the level of the top of the first row of doped zones 28. Using the first mask 36A, the locations of the doped zones 28 of the first row may be etched from the semiconductor material – creating a plurality of first spaced-apart cavities. N+ doped material may be deposited into the cavities, thereby forming the first row of doped zones 28. Addition semiconductor material may be grown on the first portion of the doped drift region 26 and the first row of doped zones 28 to form the remainder of the doped drift region 26. Using the second mask 36A, the locations of the doped zones 28 of the second row may be etched from the additional semiconductor material – creating a plurality of second spaced-apart cavities. N+ doped material may be deposited into the cavities, thereby forming the second row of doped zones 28.

Referring to block 103 and FIG. 2D, a drift region 22 is formed. The drift region 22 may be formed utilizing various deposition techniques for epitaxial crystal growth of N- doped material.

Referring to block 104 and FIG. 2E, a source 18 is formed adjacent an upper portion of the drift region 22. In the illustrated example, the source 18 includes a left side section and a right side section. Left and right wells are formed (examples of which are formed from P material), with the left P-well being formed at an upper left corner of the drift region 22, and the right P-well being formed at an upper right corner of the drift region 22. The left and right P-wells may be formed using various implantation techniques. The left side section of the source 18 (which may be an N+ material) and a left side doped region (or body contact which may be a P+ material) may be formed by implantation within the left P-well. The right side section of the source 18 (which may be an N+ material) and a right side doped region (or body contact which may be a P+ material) may be formed by implantation within the right P-well.

Referring to block 105 and FIG. 2F, a gate oxide 16 is formed on top of a portion of the drift region 22 and the source 18. The gate oxide 16 includes a thick oxide section 16A and a thin oxide section 16B. The thin oxide section 16B is grown on an upper surface of an upper portion of the drift region 22 as well as portions of the N+ region and the Pwell of each of the left and right side sections of the source 18. The thick oxide section 16A is deposited on a laterally central portion of the thin oxide section 16B, over the upper portion of the drift region 22 (the so-called JFET neck region). The thick oxide section 16A may have a thickness that is greater than a thickness of the thin oxide section 16B. In one example, the gate oxide may be formed as a single integral body, with all but the central portion being etched away so that the oxide has a thicker section over the JFET neck region of the drift region and thinner side sections extending over the well and the gate on each side of the FET. The gate oxide 16 may be formed from silicon dioxide, aluminum dioxide (Al2O3), hafnium dioxide, silicon nitride, or other suitable insulating or dielectric material.

Referring to block 106 and FIG. 2F, a gate 14 is formed on the gate oxide 16. The gate 14 is formed by depositing polysilicon, or other suitable semiconductor or metallic material, onto the gate oxide 16. Typically, the polysilicon is deposited on the entire upper surface of the volume of semiconductor material 12 (a so-called “full coat”). Then, using a mask to cover the region of the gate 14, the remainder of the polysilicon is etched away.

Referring to block 107 and FIG. 2G, a plurality of conductive contacts, or electrodes, are formed, with each contact providing electrical connection between various components and bond wires that connect to a package for the FET 10. Specifically, a gate contact 30 is formed on the gate 14, a source contact 32 is formed on the source 18, and a drain contact 34 is formed on the drain 20. Each contact is formed from metals or metal alloys may be formed using various metal deposition techniques.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well.

Additionally, in general, unless otherwise specified or unless one with ordinary skill in the art would understand otherwise, doping characterized as "++" (e.g., P++) will have a relatively higher concentration of dopants than "+" (e.g., P+) doping, "+" doping will have a relatively higher concentration than "-well" (e.g., P-well) doping, and "-well" doping will have a relatively higher concentration of doping than "-" (e.g., P-) doping. In general, doping concentrations (typically measured in parts-per-cubic-centimeter) for contact implants (e.g., sources, drains, body contacts) may be approximately between 5x10^18 and 1x10^22; doping concentrations for channel and threshold forming implants (e.g., P-wells) may be approximately between 5x10^15 and 5x10^17; doping concentrations for shielding implants may be approximately between 5x10^17 and 5x10^19; and doping concentrations for conductivity improvement implants (e.g., N- doping in the junction field-effect transistor neck region of a metal oxide semiconductor field-effect transistor) may be approximately between 1x10^17 and 1x10^19.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

Throughout this specification, references to “one example”, “an example”, or “examples” mean that the feature or features being referred to are included in at least one example of the technology. Separate references to “one example”, “an example”, or “examples” in this description do not necessarily refer to the same example and are also not mutually exclusive unless so stated and/or except as will be readily apparent to those skilled in the art from the description. For example, a feature, structure, act, etc. described in one example may also be included in other examples, but is not necessarily included. Thus, the current technology can include a variety of combinations and/or integrations of the examples described herein.

Although the present application sets forth a detailed description of numerous different examples, it should be understood that the legal scope of the description is defined by the words of the claims set forth at the end of this patent and equivalents. The detailed description is to be construed as illustrative only and does not describe each possible example since describing each possible example would be impractical. Numerous alternative examples may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the examples illustrated in the attached drawing figures, it is noted that equivalents may be employed and substitutions made herein without departing from the scope of the technology as recited in the claims.

Having thus described various examples of the technology, what is claimed as new and desired to be protected by Letters Patent includes the following:

What is claimed is:

1. A field effect transistor (FET) that is radiation-hardened against a single-event burnout effect, the FET comprising:
a volume of semiconductor material including vertically spaced first and second ends;
a gate positioned adjacent the first end of the volume of semiconductor material;
a source positioned adjacent the first end of the volume of semiconductor material;
a drain spaced apart from the source;
a drift region defined by the volume of semiconductor material positioned between the source and the drain; and
a doped drift region including a plurality of doped zones spaced apart from one another and positioned between the drain and the drift region, the doped drift region configured to provide radiation hardening against a single event burnout.

2. The FET of claim 1,
comprising a buffer layer positioned between the drain and the doped drift region,
the buffer layer being formed from doped material having a higher dopant concentration than the drain and the doped drift region.

3. The FET of claim 2,
the doped zones having a dopant concentration that is higher than the remaining portion of doped drift region but is lower than the buffer layer.

4. The FET of claim 3,
the doped zones and the drain having similar dopant concentrations.

5. The FET of claim 4,
the drift region comprising N- material,
the doped drift region comprising N- material,
the doped zones comprising N+ material,
the drain comprising N+ material,
the buffer layer comprising N++ material.

6. The FET of claim 1,
the drain being positioned at the second end of the volume of semiconductor material.

7. The FET of claim 1, comprising:
a gate oxide positioned between the gate and the source and formed from electrically insulating material or dielectric material.

8. The FET of claim 7,
the gate oxide including a thick section positioned over a JFET neck region of the drift region.

9. The FET of claim 1,
the doped zones being distributed in a plurality of rows, each row positioned at a respective one of a plurality of depths in the doped drift region.

10. The FET of claim 9,
each of the rows including a respective set of the doped zones spaced laterally apart from one another, such that adjacent ones of the doped zones in the respective set define a space therebetween.

11. The FET of claim 10,
each of the doped zones in one row being vertically aligned with the space between adjacent doped zones in one or more adjacent row(s).

12. The FET of claim 11,
each of the doped zones in one row being laterally spaced apart from neighboring doped zones in one or more adjacent row(s).

13. The FET of claim 1,
each of the doped zones having a generally rectangular cuboid shape.

14. A method of fabricating a field effect transistor comprising:
forming a volume of semiconductor material to include first and second vertically spaced ends;
forming a gate adjacent adjacent the first end of the volume of semiconductor material;
forming a source adjacent adjacent the first end of the volume of semiconductor material;
providing a drain spaced apart from the source, such that the volume of semiconductor material defines a drift region between the source and the drain; and
forming a doped drift region between the drain and the drift region,
the operation of forming the doped drift region including forming a plurality of doped zones spaced apart from one another and configured to provide radiation hardening against a single event burnout.

15. The method of claim 14, comprising:
forming a buffer layer between the drain and the doped drift region,
the operation of forming the buffer layer being performed so that the buffer layer has a higher dopant concentration than the drain and the doped drift region.

16. The method of claim 15,
the operation of forming the doped zones being performed so that the doped zones have a higher dopant concentration than the remaining portion of the doped drift region but lower than the buffer layer,
the operation of providing the drain being performed so that the drain and the doped zones have similar dopant concentrations.

17. The method of claim 14,
the operations of forming the doped drift region and the doped zones including locating the doped zones into a plurality of rows positioned at a respective depths of the doped drift region, with each of the rows including a respective set of the doped zones spaced laterally apart from one another, such that adjacent ones of the doped zones in the respective set define a space therebetween.

18. The method of claim 17,
the operation of locating the doped zones into each of the rows includes forming a doped material through a respective one of a plurality of masks, each mask including openings in a plurality of locations, each location corresponding to a lateral position of the doped zones for a given row of doped zones,
the operation of forming the doped material through the respective masks including implanting the doped material at a respective one of a plurality of energy levels which vary according to the depth of the row of doped zones.

19. The method of claim 17,
the step of locating the doped zones including vertically aligning the doped zones in one row with the space between adjacent doped zones in one or more adjacent row(s).

20. The method of claim 19,
the operation of locating the doped zones including laterally spacing the doped zones in one row from neighboring doped zones in one or more adjacent row(s).
